(19) United States
(12) Patent Application Publication
(10) Pub. No.: US 2009/0220801 A1
(43) Pub. Date: Sep. 3, 2009

(54) METHOD AND APPARATUS FOR GROWTH OF HIGH PURITY 6H-SIC SINGLE CRYSTAL

(76) Inventors: Brian Wagner, Baltimore, MD (US); Travis J. Randall, Baltimore, MD (US); Thomas J. Knight, Silver Spring, MD (US); David J. Knuteson, Ellicott City, MD (US); David Kahler, Arbutus, MD (US); Andre E. Berghmans, Owing Mills, MD (US); Sean R. McLaughlin, Severn, MD (US); Narsingh B. Singh, Ellicott City, MD (US); Mark Usefara, Baltimore, MD (US)

Correspondence Address: Dianoosh Salehi;SNELL & WILMER L.L.P., 600 Anton Boulevard, Suite 1400, Costa Mesa, CA, 92626-7689, US

(21) Appl. No.: 12/040,785

(22) Filed: Feb. 29, 2008

(51) Int. Cl. C23C 14/34; B32B 9/04

(52) U.S. Cl. 428/446; 204/192.25

(57) ABSTRACT

The disclosure relates to a method and apparatus for growth of high-purity 6H SiC single crystal using a sputtering technique. In one embodiment, the disclosure relates to a method for depositing a high purity 6H-SiC single crystal film on a substrate, the method including: providing a silicon substrate having an etched surface; placing the substrate and an SiC source in a deposition chamber; achieving a first vacuum level in the deposition chamber; pressurizing the chamber with a gas; depositing the SiC film directly on the etched silicon substrate from a sputtering source by: heating the substrate to a temperature below silicon melting point, using a low energy plasma in the deposition chamber; and depositing a layer of hexagonal SiC film on the etched surface of the substrate.

### BACKGROUND OF THE INVENTION

1. Field of the Invention

The present invention relates generally to high purity single crystal film growth for use in high performance electronic devices. More specifically, the disclosure relates to large diameter, low defect, high quality SiC substrates having 6H-type single crystals and semiconductor devices made therefrom.

2. Description of Related Art

Silicon Carbide (“SiC”) has become an important wide bandgap semiconductor material because of its excellent properties for high power microwave devices. SiC now competes with GaAs and pure silicon in terms of gain, power output and efficiency at X-band. SiC promises even better performance at the higher frequencies (i.e., Ka and Ku-bands). Broadband power RF transmitters are needed with high efficiency, high linearity and low noise for transceiver modules. Silicon carbide crystallizes in more than 200 different modifications or polytypes. The most important polytypes include the so-called 2C 4H and 6H, where “C” denotes cubic and “H” denotes hexagonal crystalline shape. As used herein, the terms 6H crystalline SiC and hexagonal SiC are interchangeable.

The material attributes of SiC makes it desirable for constructing communication and power devices. Such attributes include a relatively wide bandgap, a high thermal conductivity, high breakdown field strength and a high electron saturation velocity. SiC is commonly used in the bipolar junction transistors (“BJT”) and the Schottky diodes. BJTs are defined by two back-to-back p-n junctions formed in a semiconductor material. In operation, current enters a region of the of semiconductor material adjacent one of the p-n junctions called the emitter. Current exists the device from a region of the material adjacent the other p-n junction, called the collector. The collector and the emitter have the same conductivity type. A thin layer of semiconductor material, called the base, is positioned between the collector and the emitter. The base has opposite conductivity to the conductor and the emitter. High purity 6H SiC has been found to be advantageous for use in bipolar junction transistors.

Similarly, diodes made of 4H SiC have been known to rapidly degrade and exhibit a growth of stacking faults under a forward bias application. In contrast, diodes made of 6H SiC have been substantially less likely to degrade under a similar forward bias. Thus, high purity 6H SiC diodes have been advantageous.

SiC is also used as a substrate for microwave devices. Such devices typically include depositions of GaN, AlN and InN on the substrate. Conventional applications have resulted in defective nitride film deposition, rendering the semiconductor device unreliable. The problem arises because of the lattice mismatch between the GaN layer and the Si substrate. It is known that the lattice constant of SiC is closer to that of GaN, thereby providing less of lattice mismatch problem. However, the excessive production cost of SiC prohibits wide use of the material as a common substrate.

Accordingly, there is a need for a method and process of economical manufacturing of SiC on a Si wafer. There is also a need for a method and process for production of high purity single-crystal 6H silicon.

### SUMMARY OF THE INVENTION

In one embodiment, the disclosure relates to a method for depositing a high purity 6H-SiC single crystal film on a substrate, the method comprising: providing a silicon substrate having an etched surface; placing the substrate and an SiC source in a deposition chamber; achieving a first vacuum level in the deposition chamber; pressurizing the chamber with a gas; depositing the SiC film directly on the etched silicon substrate from a sputtering source by: heating the substrate to a temperature below silicon melting point, using a low energy plasma in the deposition chamber; and depositing a layer of hexagonal SiC film on the etched surface of the substrate.

In another embodiment, the disclosure relates to a semiconductor diode prepared by a process comprising the steps of: providing a silicon substrate; depositing an SiC layer over silicon substrate by sputtering, the SiC layer is characterized by having substantially a 6H crystalline structure and having a FWHM in the range of about 2.0 degrees or greater; wherein the sputtering SiC over Si is implemented at a temperature below the melting point of the silicon substrate.

### BRIEF DESCRIPTION OF THE DRAWINGS

The principles of the disclosure, as well as the objects and advantages thereof, will become readily apparent from consideration of the following specification in conjunction with the accompanying drawings in which like reference numerals designate like parts throughout the figures thereof and wherein:

FIG. 1 shows the sputtering system used for depositing a layer of 6H SiC on a Si substrate according to an embodiment of the disclosure;

FIG. 2 is the result of the x-ray diffraction scan showing both the Si 111 substrate peaks and the 6H SiC film processed according to an embodiment of the disclosure;

FIG. 3 is a rocking curve of the SiC film processed according to an embodiment of the disclosure;

FIG. 4 is an AFM scan showing the morphology of the SiC film processed according to an embodiment of the disclosure;

FIG. 5 is a three-dimensional illustration of the surface microstructure from the AFM of FIG. 4;

FIG. 6 is the 60° periodicity of the 103 reflections in the SiC film prepared according to the embodiments of the disclosure;

FIG. 7 is the comparison of the measured refractive index values for the deposited SiC films according to the embodiments disclosed herein as compared to known values for SiC;

FIG. 8 is a structure of a diode device prepared according to the method disclosed herein;

FIG. 9 shows the results of the x-ray diffraction of hexagonal AlN film with an orientation mimicking that of the Si substrate and 6H SiC film;

FIG. 10 shows x-ray rocking curve of the AlN film with a FWHM value of about 7441 arcsec or approximately 2.0 degrees;

FIG. 11 shows x-ray diffraction omega-2 theta curves showing GaN and AlGaN peaks; and

FIG. 12 shows an overlay of IV characteristics for three diodes prepared according to the embodiments of the disclosure.

### DETAILED DESCRIPTION

The disclosure relates to a method and apparatus for producing high purity 6H SiC. More specifically, the disclosure relates to a method and apparatus for producing cost-effective, high purity semiconductor structure comprising of a silicon substrate having thereon a SiC film which includes, substantially exclusively, 6H crystalline structure. While the inventive embodiments disclosed herein are illustrated with reference to 6H SiC film used in a diode or a semiconductor device, it should be noted that such embodiments are exemplary in nature and the principles disclosed herein are not limited thereto.

Conventional deposition techniques grow SiC on a silicon substrate at temperatures approaching 2000° C. The relatively high deposition temperature is due to the fact that silicon grows better at temperatures approaching 2000° C. While such temperatures allow deposition of 6H SiC, they far exceed the melting point temperature of silicon, which is about 1150° C. Consequently, the deposition and growth of SiC occurs over melted silicon. Moreover, the conventional techniques are limited to using chemical vapor deposition which provide little control over the crystalline configuration of 6H SiC.

To overcome these and other deficiencies, an embodiment of the disclosure relates to hexagonal SiC films deposited on Si substrate using plasma sputtering techniques while maintaining the deposition temperature below silicon's melting point. The deposition can be reactive or non-reactive sputtering.

In one embodiment, a high purity 6H-SiC single crystal film is deposited on a silicon substrate by providing a silicon substrate having an etched surface. Conventional etching techniques can be used to remove impurities prior to deposition. The deposition chamber pressure is reduced to a first vacuum level and the etched substrate is placed in the chamber along with an SiC source. The chamber is then pressurized with an atmospheric gas such as argon or an argon/methane mixture. For example, the chamber can be pressurized to about 5-8 mtorr. The SiC film can be deposited or grown directly on the etched silicon substrate from a sputtering source while the substrate and the source are maintained at a temperature below silicon's melting point. In one embodiment, low energy plasma is used in the deposition chamber. The final SiC film can comprises of substantially entirely of 6H SiC. In another embodiment, the final film comprises about 85% 6H SiC.

A deposition chamber for DC deposition or RF deposition can also be used. Additionally, the deposition chamber can be heated to about 800-900° C., or about 800-1100° C. prior to the deposition. In an exemplary application, one or both of the Si substrate or the SiC source were rotated with respect to each other during the deposition.

The film can be deposited to any desired thickness. The SiC film can be thin as a few angstroms or as thick as a hundred microns. The required thickness is dictated by a number of factors related to device performance. In one application, an SiC film was deposited to a thickness of about 0.4 microns.

The Si substrate can be of any size or thickness. In an exemplary implementation, a two inch, single-side polished Si wafer was used as a substrate. The Si wafer was etched in 10% hydrofluoric acid (HF) to remove any native oxide. Subsequently, the wafer was dried with nitrogen gas and then loaded into a growth chamber.

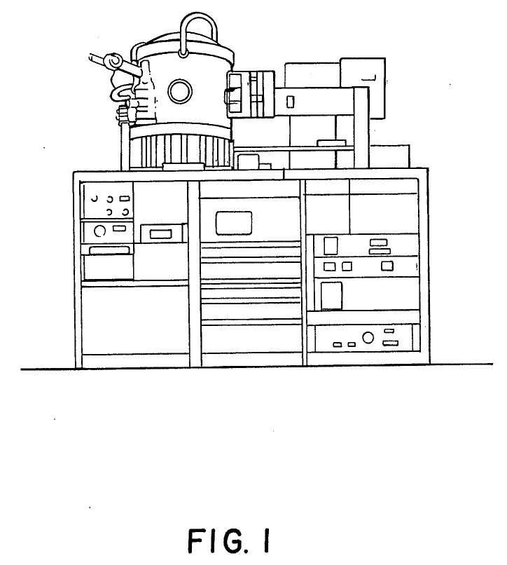

FIG. 1 shows the sputtering system used for the deposition of 6H SiC on Si substrate. DC and RF plasmas can be used to deposit the SiC film on an Si substrate.

The SiC on Si deposition can also be achieved by using different target materials. An Si target can be used in a methane containing atmosphere for reactive sputtering. Also, separate Si and C targets can be used to deposit the SiC film on Si substrate. DC plasma can also be used in place of RF plasma. DC plasma can provide a greater control of the deposition, especially when reactively sputtering SiC.

For the SiC films on Si to be used as a substrate of GaN HEMT or related high frequency nitride devices, semi-insulating Si should be selected over n-type or p-type Si. This implementation is advantageous in that it avoids a parasitic capacitance produced from having a conductive substrate beneath devices in high-frequency operations. The sputtered SiC layer can prevent unintentional p-type doping during the deposition of AlN on a substrate. Conductive substrates can produce parasitic capacitance during high-frequency device operation.

The exemplary RF sputtered SiC on Si achieved a growth rate of up to 37 Å/minute and the resulting film was free of cracks. The film was grown to a thickness of 1.31 cm. The resulting film was tested with x-ray diffraction and the result confirmed the deposition of 6H SiC on Si substrate.

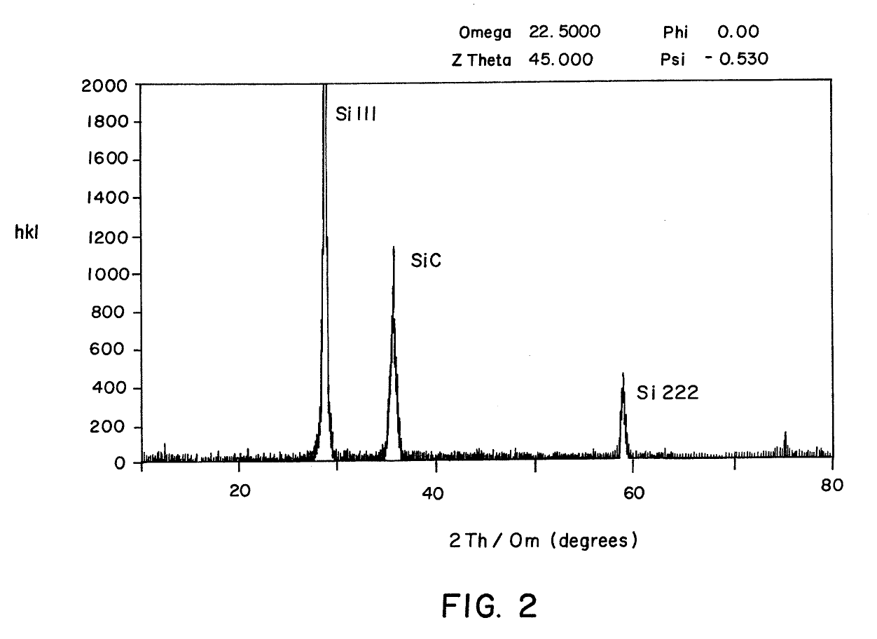

FIG. 2 is the result of the x-ray diffraction scan showing both the Si substrate peaks and the hexagonal SiC peaks. Referring to FIG. 2 it can be seen that Si 111 and Si 222 are present as indicated by different peaks. Only one peak representing SiC was obtained from the x-ray diffraction. This proves that a single crystal type of SiC (6H SiC), and not other polytypes or orientations of SiC were deposited.

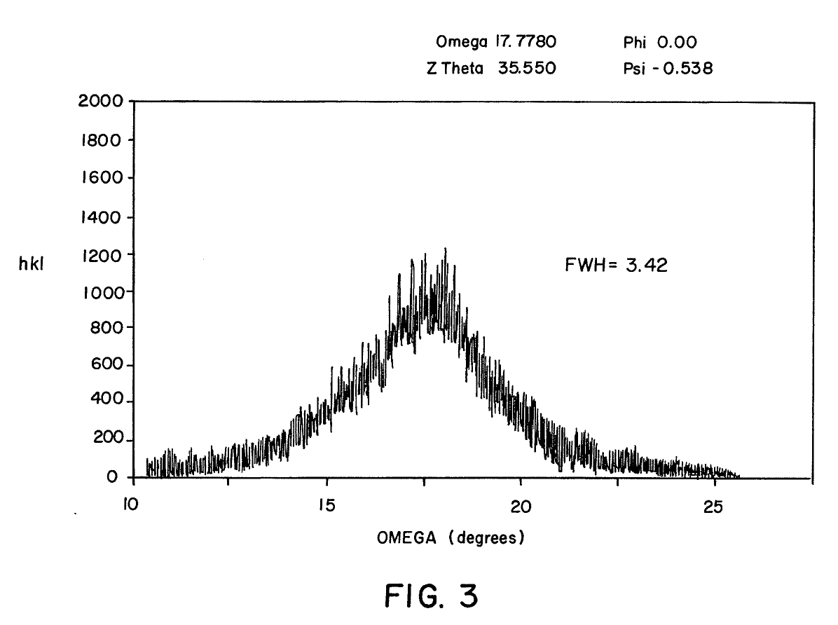

FIG. 3 is a rocking curve of the SiC film that displays a FWHM and can be as low as 2.0 degrees. Poly-crystalline SiC would have no FWHM. The results of FIG. 3 shows the presence of a substantially pure 6H SiC.

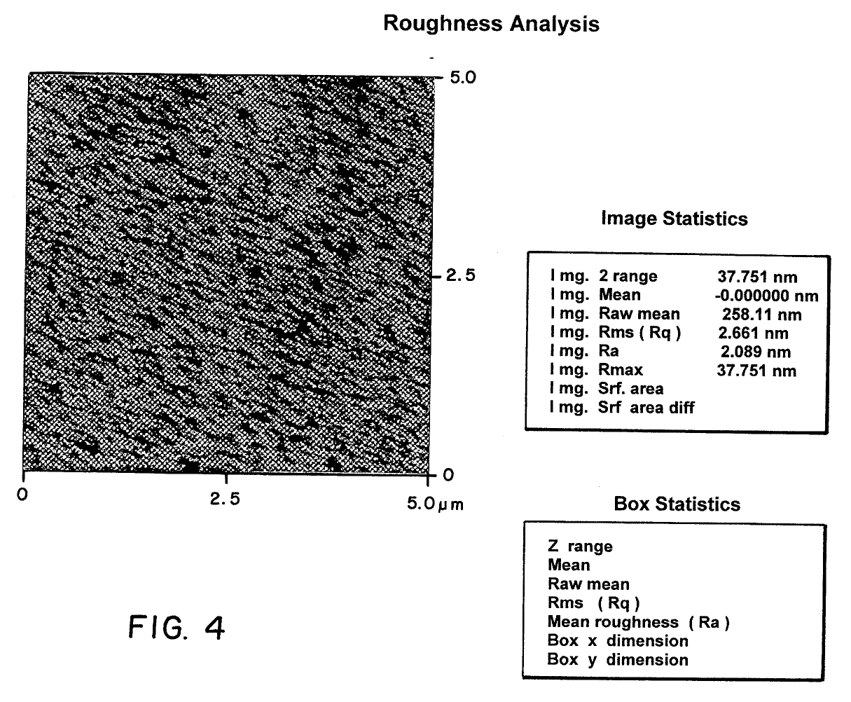

FIG. 4 is an atomic force microscope (AFM) scan showing the grains of the SiC film. As can be seen, the grain size was approximately 250 nm and fairly uniform. The surface roughness had an RMS value of about 2.66 nm. Low RMS roughness values indicate good film quality and is an indication of a device-ready surface

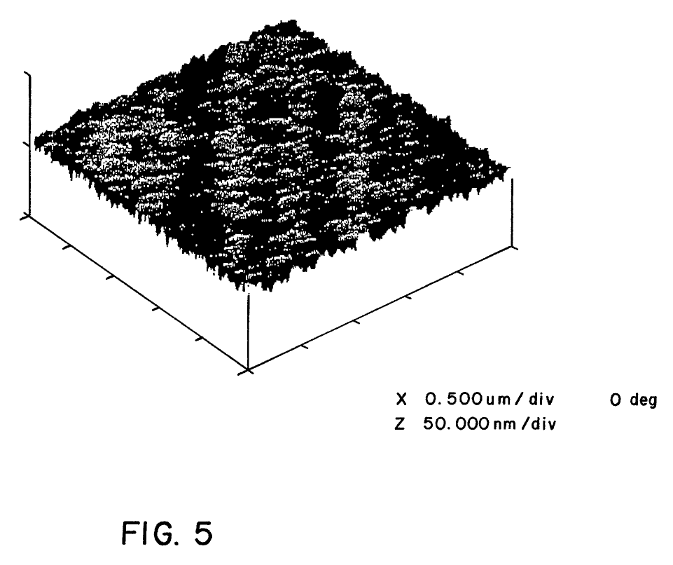

FIG. 5 is a three-dimensional rendering of the surface microstructure from an atomic force microscope.

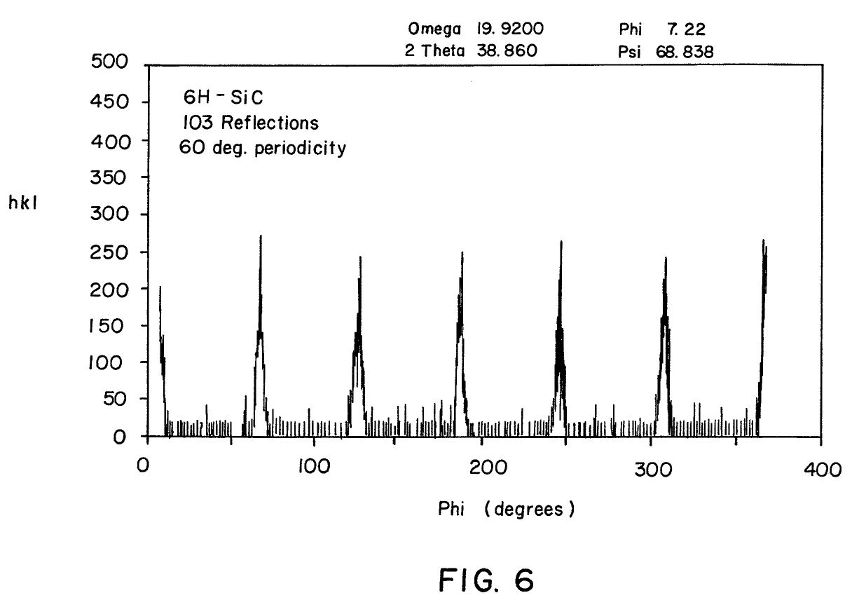

FIG. 6 is a rotational scan showing the 60 degree periodicity of the 103 reflection in 6H SiC, further verifying the hexagonal structure of the deposited SiC film.

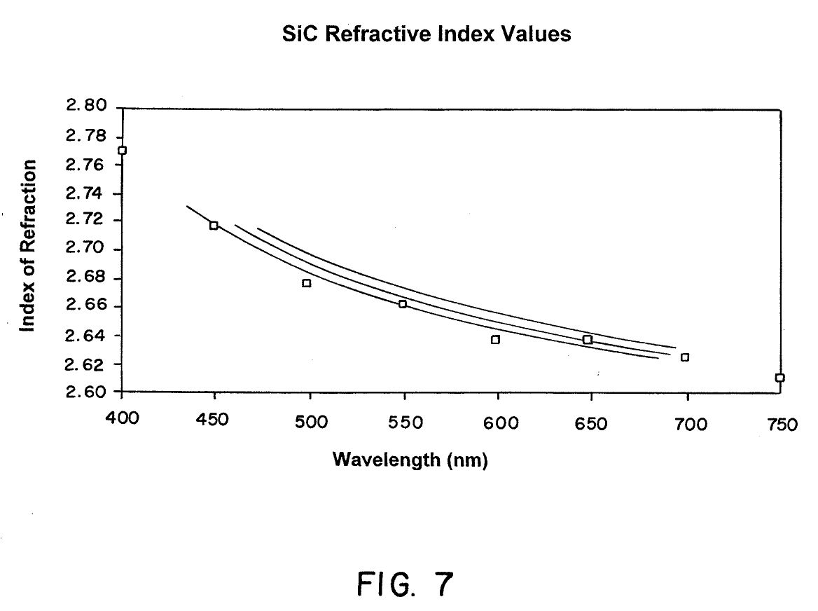

FIG. 7 has the refractive index of the SiC file prepared according the embodiments of the invention plotted against known SiC refractive index values. Refractive index can be influenced by a number of factors including, purity, polytype, stoichiometry, and overall film defectiveness. By virtue of the previously mentioned SiC film having similar values to accepted refractive index values, the quality of the can be inferred.

In one embodiment, the disclosure relates to a method and apparatus for processing a diode comprising SiC/Si. As stated, SiC is an important wide bandgap semiconductor because of excellent properties for high power microwave devices. SiC competes with GaAs and Si in terms of gain, power output and efficiency at x-band and can afford even better performance at higher frequencies of Ka- and Ku-bands.

In preparation of an SiC/Si diode, hexagonal SiC films were deposited on an Si substrate using RF plasma sputtering with resistive heating of the Si substrate. A two inch Si wafer was etched in 10% HF acid to remove native oxides. Subsequently, the wafer was dried with nitrogen gas and then loaded into the growth chamber similar to the chamber shown in FIG. 1. The Si substrate was clamped onto a 2″ resistive heater and the chamber was evacuated to a base pressure of about 5e-8 Torr. Once the base pressure was reached, the substrate/heater assembly was ramped up to 850° C. growth temperature at a 3° per minute ramp rate. Argon gas was used as the RF plasma gas. The argon gas flow was set to 50 sccm, and the chamber was maintained at about 8 mTorr during the deposition process.

During deposition, the chamber was actively pumped. The RF forward power was 100 Watts with a DC bias of approximately −250V. The sputter gun used a 3″ SiC target. It should be noted that SiC can be deposited on a Si deposition in any known manner without departing form the principles disclosed herein. For example, an Si target can be used in a methane atmosphere for reactive sputtering. Also, separate Si and C targets can be employed for depositing SiC on Si. DC plasma can also be used in the place of RF plasma which could provide greater control on the deposition process, especially when reactively sputtering SiC.

RF sputtered SiC on Si achieved growth rate of up to 37 Å/min and the resulting SiC layer was a crack-free film void of any cosmetic defects. The SiC film was grown to a thickness of about 1.31 μm. X-ray diffraction confirms the deposition of hexagonal SiC on Si 111 substrate. FIG. 2 is the x-ray diffraction scan showing both the Si 111 substrate peaks and the hexagonal SiC peak.

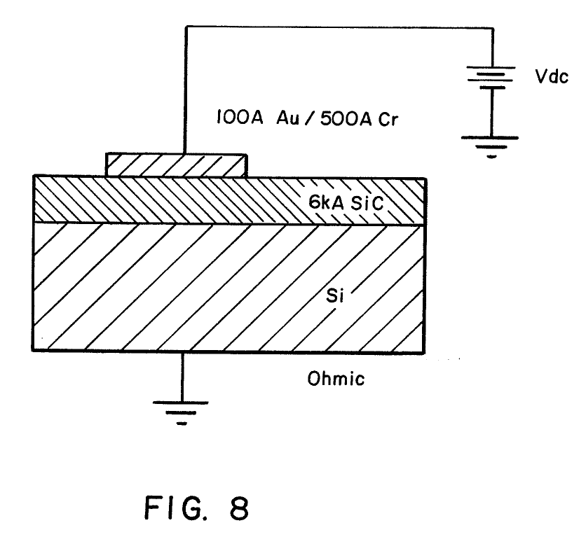

FIG. 8 schematically illustrates a diode prepared according to the embodiments of the disclosure. The electrical testing on the finished diode was performed using a Keithly 4200 Semiconductor Characterization System. The current-voltage (IV) characteristics of the devices were characterized using the Keithly Interactive Testing Environment. Three diodes were prepared and placed under DC bias between the Au/Cr contact on the top surface (anode) and the Ohmic contact created between the tester vacuum chuck and the Si substrate. The diodes were created by lithographic patterning and evaporation of Cr/Au contacts to the SiC film surface. The bias was swept from −10 to +10 volts and each device current was measured.

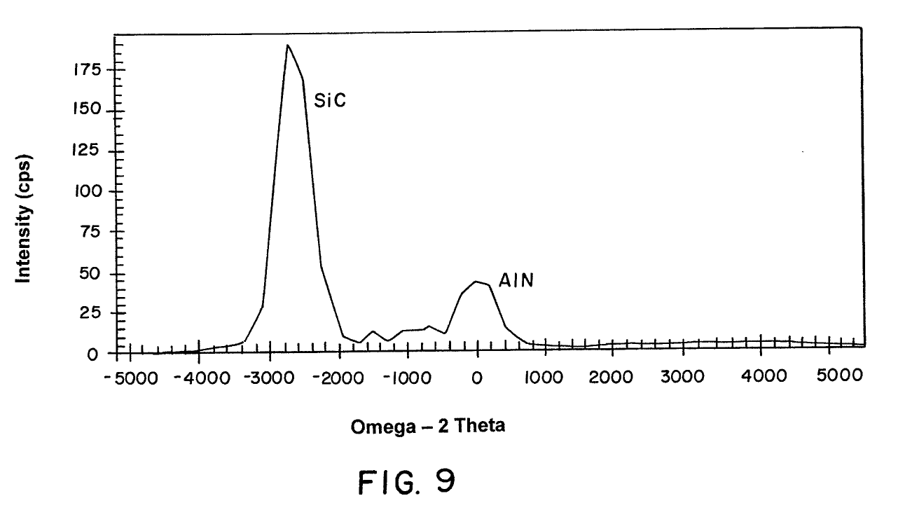

In another illustrative example, a layer of AlN film with a thickness of about 1000 Å was deposited on the previously-prepared SiC film on Si substrate. Metal Organic Chemical Vapor Deposition (“MOCVD”) was used for depositing the AlN film over the SiC layer. The final structure was then tested with x-ray diffraction and the results are shown at FIG. 9. The x-ray pattern of FIG. 9 confirms the presence of single crystalline type 6H SiC and AlN. There is no indication of significant presence of polytypes in FIG. 9. Also, the orientation shown in FIG. 9 mimics that of the Si substrate and 6H SiC film.

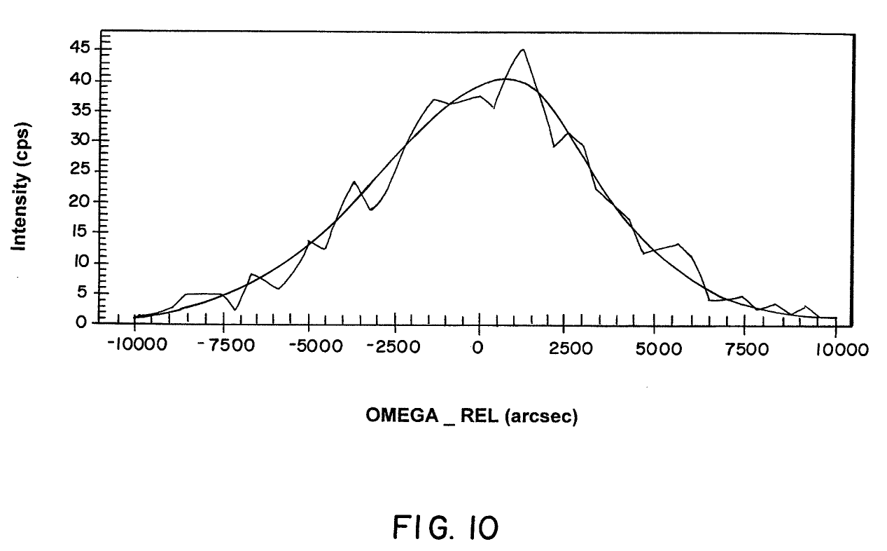

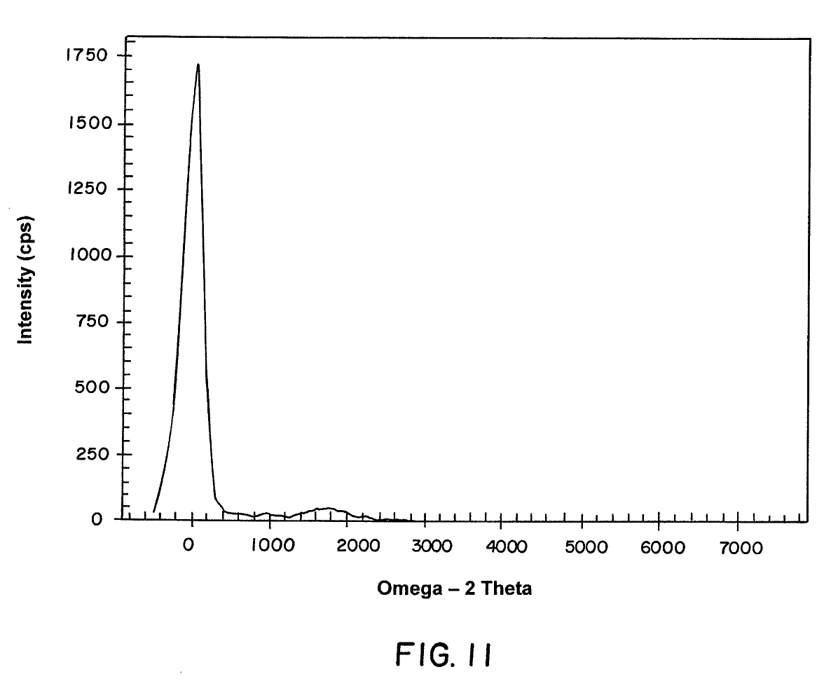

FIG. 10 shows x-ray rocking curve of the AlN film with a FWHM value of about 7441 arcsec at 2.0 degrees. This is significant because it shows that the AlN film is oriented with the Si substrate, the deposited SiC film, and is epitaxial and single crystalline.

A further experiment was conducted by growing a layer of GaN film on the AlN layer prepared above. FIG. 11 shows a single peak of GaN as depicted by x-ray diffraction curve. More specifically, FIG. 11 shows an x-ray of omega-2 theta curve showing GaN and AlGaN peaks. As shown in FIG. 8, a single peak of GaN with FWHM of 2360 arcsec was obtained which demonstrates lattice compatibility between the new layers and the underlying 6H SiC.

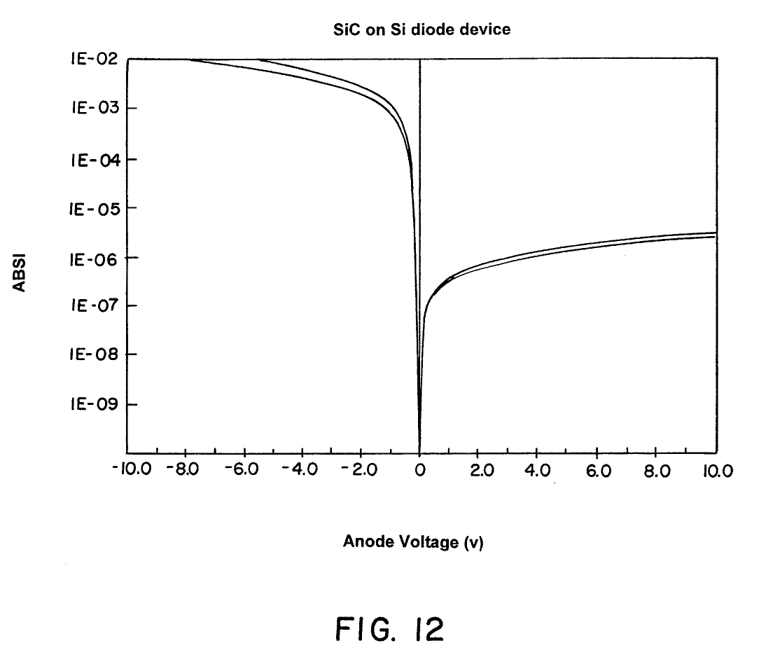

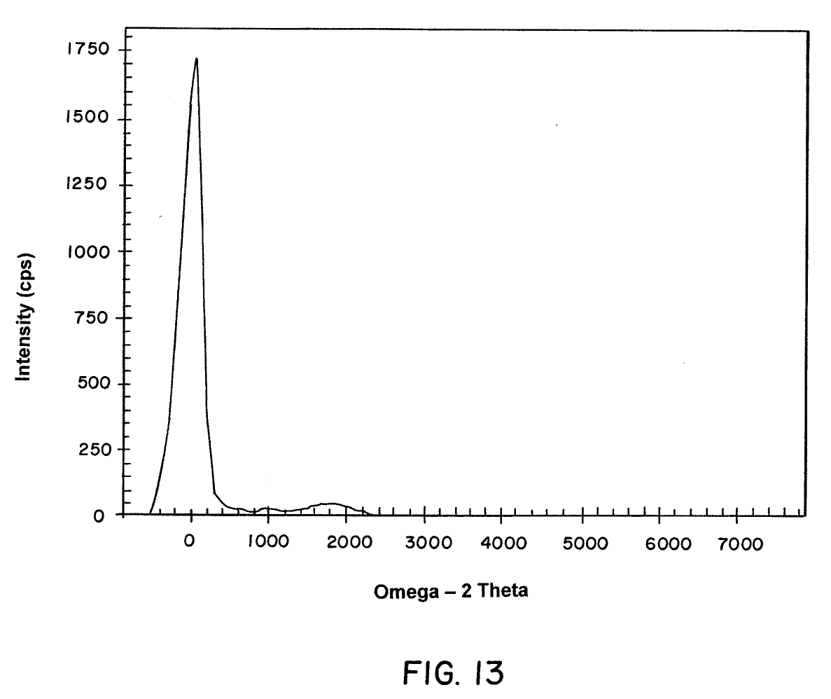

FIG. 12 shows the IV characteristics of three tested devices overlaid on the same plot. The diodes exhibited rectifying behavior characteristics of a diode device. This indicates that a working semiconductor device was created with the deposited SiC film as an active device material. In FIG. 12 forward bias operation of the diode was achieved at negative DC bias, but this is simply a function of the polarity choice in the test setup. This result indicates successful diode fabrication and testing.

While the specification has been disclosed in relation to the exemplary embodiments provided herein, it is noted that the inventive principles are not limited to these embodiments and include other permutations and deviations without departing from the spirit of the disclosure.

What is claimed is:

1. A method for depositing a high purity 6H-SiC single crystal film on a substrate, the method comprising:
providing a silicon substrate having an etched surface;
placing the substrate and an SiC source in a deposition chamber;
achieving a first vacuum level in the deposition chamber;
pressurizing the chamber with a gas;
depositing the SiC film directly on the etched silicon substrate from a sputtering source by:
heating the substrate to a temperature below silicon melting point,
using a low energy plasma in the deposition chamber; and
depositing a layer of hexagonal SiC film on the etched surface of the substrate.

2. The method of claim 1, wherein the deposited SiC film comprises 6H-SiC with a purity of at least 85%.

3. The method of claim 1, wherein the deposition chamber is configured for one of DC deposition or RF deposition.

4. The method of claim 1, wherein the step of heating the substrate to a temperature below silicon melting point comprises heating the substrate to about 800-900° C.

5. The method of claim 1, wherein the step of heating the substrate to a temperature below silicon melting point comprises heating the substrate to about 800-1100° C.

6. The method of claim 1, wherein the step of depositing the SiC film further comprises rotating one or both of the Si substrate or the SiC source with respect to each other during the deposition.

7. The method of claim 1, wherein the step of depositing the SiC film further comprises: vacuuming the deposition chamber to a first vacuum pressure; heating the substrate to a deposition temperature below silicon melting point; upon reaching the deposition temperature, starting a plasma deposition process; and cooling the deposition chamber after completion of deposition.

8. The method of claim 1, wherein the step of pressurizing the chamber with a gas further comprises pressurizing the chamber with one of Argon or an Argon/methane mixture.

9. The method of claim 1, wherein the deposition chamber is pressurized to about 5-8 mtorr during the deposition step.

10. A semiconductor structure prepared according to the method of claim 1.

11. A semiconductor diode prepared by a process comprising the steps of:
providing a silicon substrate;
depositing an SiC layer over silicon substrate by sputtering, the SiC layer is characterized by having substantially a 6H crystalline structure and having a FWHM in the range of about 2.0 degrees or greater;
wherein the sputtering SiC over Si is implemented at a temperature below the melting point of the silicon substrate.

12. The semiconductor diode of claim 11, wherein the sputtering step is one of reactive or non-reactive sputtering.

13. The semiconductor diode of claim 11, wherein the SiC layer is in direct contact with the silicon substrate.

14. The semiconductor diode of claim 11, wherein the temperature below the melting point of the silicon substrate is in the range of about 800-900° C.

15. The semiconductor diode of claim 11, wherein the 6H crystalline structure has a thickness in the range of about 0.3-0.5 μm.

16. The semiconductor diode of claim 11, further comprising a material deposited over the SiC layer.

17. A method for forming a 6H-SiC single crystal film on a substrate, the method comprising:
providing a substrate with an etched surface;
providing a sputtering chamber in a substantially vacuum state;
introducing the substrate to the chamber;
heating the chamber to temperature below a melting temperature of the substrate;
pressurizing the chamber; and
sputtering SiC film directly on the etched silicon by using a low energy plasma in the deposition chamber;
wherein the film is substantially pure 6H SiC single crystal film.

18. The method of claim 17, wherein the substrate is a silicon substrate.

19. The method of claim 17, wherein the sputtering chamber is configured for one of DC deposition or RF deposition.

20. The method of claim 17, wherein the step of heating the substrate to a temperature below silicon melting point comprises heating the substrate to about 800-900° C.

21. The method of claim 17, wherein the step of depositing the SiC film further comprises: vacuuming the deposition chamber to a first vacuum pressure; heating the substrate to a deposition temperature below silicon melting point; upon reaching the deposition temperature, starting a plasma deposition process; and cooling the deposition chamber after completion of deposition.

22. The method of claim 17, wherein the step of pressurizing the chamber further comprises pressurizing the chamber with one of Argon or an Argon/methane mixture to a pressure of about 5-8 mtorr.

23. A semiconductor structure prepared according to the method of claim 17.
